(19) United States
(12) Patent Application Publication
(10) Pub. No.: US 2026/0186689 A1
(43) Pub. Date: Jul. 2, 2026

(54) MEMORY DEVICE MONITORING INTERNAL VOLTAGE AND MEMORY SYSTEM INCLUDING THE SAME

(71) Applicant: SK hynix Inc., Icheon-si Gyeonggi-do (KR)

(72) Inventors: Dong Ju YANG, Icheon-si Gyeonggi-do (KR); Tae Ho KIM, Icheon-si Gyeonggi-do (KR); Hyeon Jin YANG, Icheon-si Gyeonggi-do (KR); Se Jun HAN, Icheon-si Gyeonggi-do (KR)

(73) Assignee: SK hynix Inc., Icheon-si Gyeonggi-do (KR)

(21) Appl. No.: 19/239,114

(22) Filed: Jun. 16, 2025

(30) Foreign Application Priority Data
Dec. 30, 2024 (KR) 10-2024-0201426

(51) Int. Cl. G06F 3/06

(52) U.S. Cl. CPC G06F 3/0653; G06F 3/0604; G06F 3/0673

(57) ABSTRACT

A memory device includes a base die configured to monitor a first core monitoring voltage output from a first core die and a second core monitoring voltage output from a second core die, through a voltage monitoring pad. The first core die is stacked over the base die through a first through-via connected to the voltage monitoring pad and outputs the first core monitoring voltage to the voltage monitoring pad through the first through-via after connecting the first through-via to ground voltage. The second core die is stacked over the first core die through a second through-via connected to the voltage monitoring pad and outputs the second core monitoring voltage to the voltage monitoring pad through the second through-via after connecting the second through-via to the ground voltage.

### CROSS-REFERENCE TO RELATED APPLICATIONS

The present application claims priority under 35 U.S.C. § 119(a) to Korean Application No. 10-2024-0201426, filed in the Korean Intellectual Property Office on Dec. 30, 2024, the entire contents of which application is incorporated herein by reference.

### BACKGROUND

### 1. Technical Field

The present disclosure relates to memory devices and memory systems including the same.

### 2. Related Art

Stack memory systems such as high bandwidth memory (HBM) devices are used in a wide range of applications due to their high bandwidth and energy efficiency. Unlike conventional memory systems that use parallel data buses, stack memory systems include a stack memory device including a base die and a plurality of core dies interconnected by through-silicon vias (TSVs). The stack memory device includes a physical interface, such as a physical layer for communication with a processor. The physical layer is designed for high speed data transmission and efficient communication.

### SUMMARY

The present disclosure describes a memory system that may include a first core die stacked with a second core die, and a base die configured to monitor a first core monitoring voltage output from the first core die and a second core monitoring voltage output from the second core die through a voltage monitoring pad. The first core die may be stacked over the base die through a first through-via connected to the voltage monitoring pad and outputs the first core monitoring voltage to the voltage monitoring pad through the first through-via after connecting the first through-via to ground voltage. The second core die may be stacked over the first core die through a second through-via connected to the voltage monitoring pad and outputs the second core monitoring voltage to the voltage monitoring pad through the second through-via after connecting the second through-via to the ground voltage.

The present disclosure describes a memory system that may include a core die and a base die configured to monitor a first core monitoring voltage output from the core die through a first voltage monitoring pad and a second core monitoring voltage output from the core die through a second voltage monitoring pad. The core die may be stacked over the base die through a first through-via connected to the first voltage monitoring pad and a second through-via connected to the second voltage monitoring pad, output the first core monitoring voltage to the first voltage monitoring pad through the first through-via, and output the second core monitoring voltage to the second voltage monitoring pad through the second through-via, after connecting the first through-via and the second through-via to ground voltage.

The present disclosure describes a memory system that may include an interposer stacked over a substrate, and a memory device and a processor stacked over the interposer and connected through a plurality of interconnections inside the interposer. The memory device may include a base die and a plurality of core dies stacked over the interposer and using a plurality of through-vias. After connecting the plurality of through-vias to ground voltage, the plurality of core dies may generate a core monitoring voltage from a peripheral voltage and a core voltage and outputs the core monitoring voltage to the plurality of through-vias. The base die may receive the core monitoring voltage output from one of the plurality of core dies through the plurality of through-vias connected to a voltage monitoring pad. The processor may monitor the core monitoring voltage at the voltage monitoring pad.

The present disclosure describes a method that may include connecting to ground voltage a first through-via and a second through-via, wherein a core die is stacked over a base die through a first through-via connected to a first voltage monitoring pad and a second through-via connected to a second voltage monitoring pad; outputting the first core monitoring voltage to the first voltage monitoring pad through the first through-via and outputting the second core monitoring voltage to the second voltage monitoring pad through the second through-via; and monitoring, by the base die, a first core monitoring voltage output from the core die through a first voltage monitoring pad and a second core monitoring voltage output from the core die through a second voltage monitoring pad.

### BRIEF DESCRIPTION OF THE DRAWINGS

FIG. 1 illustrates a memory system according to an embodiment of the present disclosure.

FIG. 2 illustrates a base die according to an embodiment of the present disclosure.

FIG. 3 illustrates a base voltage generation circuit according to an embodiment of the present disclosure.

FIG. 4 illustrates a first voltage division circuit according to an embodiment of the present disclosure.

FIG. 5 illustrates a first voltage division circuit according to an embodiment of the present disclosure.

FIG. 6 illustrates a first base selection transmission circuit according to an embodiment of the present disclosure.

FIG. 7 illustrates a second base selection transmission circuit according to an embodiment of the present disclosure.

FIG. 8 illustrates a first core die according to an embodiment of the present disclosure.

FIG. 9 illustrates a core selection signal generation circuit according to an embodiment of the present disclosure.

FIG. 10 illustrates a core enable signal generation circuit according to an embodiment of the present disclosure.

FIG. 11 illustrates a first core selection transmission circuit according to an embodiment of the present disclosure.

FIG. 12 illustrates a second core selection transmission circuit according to an embodiment of the present disclosure.

FIG. 13 and FIG. 14 are tables including internal voltage data monitored during a voltage monitoring operation according to an embodiment of the present disclosure.

### DETAILED DESCRIPTION

The cross-hatching throughout the figures illustrates corresponding or similar areas between the figures rather than indicating the materials associated with the areas.

Terms such as “first” and “second” are used to distinguish between various elements and do not imply size, order, priority, quantity, or importance of the elements. For example, a first element may be named as a second element in one example, and the second element may be named as a first element in another example.

When one component is identified as “connected” to another component, the components may be connected directly or through an intervening component between the components. When two components are identified as “directly connected,” one component is directly connected to the other component without an intervening component between the two components.

A logic “high” level and a logic “low” level may be used to describe logic levels of electric signals. A signal at a logic high level is distinguished from a signal at a logic low level. For example, when a signal at a first voltage corresponds to a signal at a logic high level, a signal at a second voltage corresponds to a signal at a logic low level. In an embodiment, the logic high level may be a voltage level that is higher than a voltage level of the logic low level. Logic levels of signals may be different or opposite according to the embodiments. For example, a signal at a logic high level in one embodiment may be at a logic low level in another embodiment, and a signal at a logic low level in one embodiment may be at a logic high level in another embodiment.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

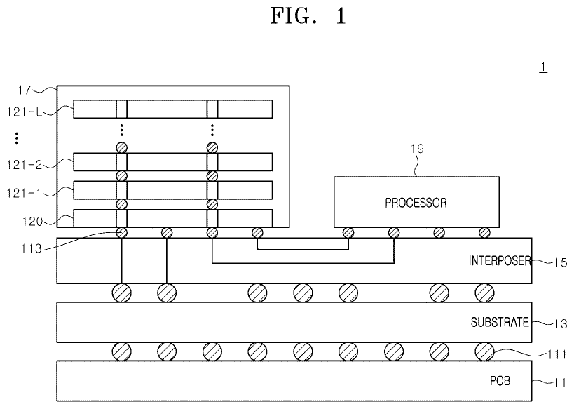

FIG. 1 illustrates a memory system 1 according to an embodiment of the present disclosure.

As shown in FIG. 1, the memory system 1 includes a printed circuit board (PCB) 11, a substrate 13, an interposer 15, a memory device 17, and a processor 19.

The printed circuit board 11 connects various electronic components to each other to form an electronic circuit (not shown). A copper (Cu) layer, a solder mask, a silk screen, and so forth are formed on the printed circuit board 11. A circuit path that transmits or transfers signals or power is formed in the copper layer. The solder mask prevents damage to the circuit and protects a specific region where components can be soldered. The silk screen indicates location or information for the electronic components as letters or symbols printed on a surface of the printed circuit board 11.

The substrate 13 is disposed over the printed circuit board 11 with bump pads in between, for example, bump pads 111 that mechanically support the interposer 15, the memory device 17, and the processor 19. The substrate 13 functions as a physical base for the printed circuit board 11 and is an insulator. The substrate 13 may include materials such as FR4, that is an insulator made of fiberglass and epoxy resin, ceramics that can withstand high temperatures, have appropriate thermal conductivity properties, and are used in high-frequency circuits, polyimide, that is used as a basic material for flexible PCBs due to flexible characteristics, and the like.

The interposer 15 is disposed over the substrate 13 with bump pads 111 in between and includes wiring that connects electronic components, for example, the memory device 17 and the processor 19, that have form factors or pin arrangements do not match or have different spacing.

The memory device 17 is disposed over the interposer 15 with pads in between, for example, micro-bump pad 113. The memory device 17 stores data received from the processor 19 and outputs the stored data to the processor 19 under control of the processor 19. The memory device 17 includes a base die 120 and a plurality of core dies 121-1 to 121-L, where L is an integer greater than 1. The core dies 121-1 to 121-L are stacked over the base die 120 with the micro-bump pads 113 in between. The base die 120 is vertically connected to the core dies 121-1 to 121-L using through-vias. The base die 120 and the plurality of core dies 121-1 to 121-L are stacked prior to a voltage monitoring operation. The base die 120 and the plurality of core dies 121-1 to 121-L are stacked vertically using the through-vias after connecting the through-vias to ground voltage VSS prior to the voltage monitoring operation. The base die 120 controls efficient data transmission between the processor 19 and the core dies 121-1 to 121-L. The base die 120 receives an input/output power voltage (voltage drain drain for IO also referred to as output stage drain power voltage) VDDQ as an operating voltage utilized during operation of internal circuits included in the base die 120. The base die 120 receives the input/output power voltage VDDQ from the printed circuit board 11 through the substrate 13 and the interposer 15. The input/output power voltage VDDQ is a voltage supplied to buffers that transmit data and is distinguished or different from the power supply voltage VDD. The base die 120 receives the power supply voltage VDD from the printed circuit board 11 through the substrate 13 and the interposer 15. The core dies 121-1 to 121-L generate a peripheral voltage VPERI from the power supply voltage VDD received through the base die 120. The core dies 121-1 to 121-L generate the peripheral voltage VPERI at a lower voltage level than the power supply voltage VDD and use the peripheral voltage VPERI in a peripheral region to control a core region. The core dies 121-1 to 121-L generates a core voltage VCORE from the power supply voltage VDD received through the base die 120. The core dies 121-1 to 121-L generate the core voltage VCORE at a lower voltage level than the power supply voltage VDD and use the core voltage VCORE in the core region including memory cells. The core dies 121-1 to 121-L generate and use multiple internal voltages, such as the peripheral voltage VPERI and the core voltage VCORE. Each of the core dies 121-1 to 121-L includes a plurality of channel regions that operate independently. Each of the plurality of channel regions is allocated with an independent operating channel to receive or transmit data. Each of the plurality of channel regions includes the peripheral region and the core region that receives and transmits data. The quantity L of core dies 121-1 to 121-L may be four, eight, twelve, sixteen, and so forth. For example, when each of the core dies 121-1 to 121-12 has eight channels, the core dies 121-1 to 121-4, the core dies 121-5 to 121-8, and the core dies 121-9 to 121-12 transmit and receive data with the processor 19 in units of a rank including thirty-two channels, including thirty-two channel regions.

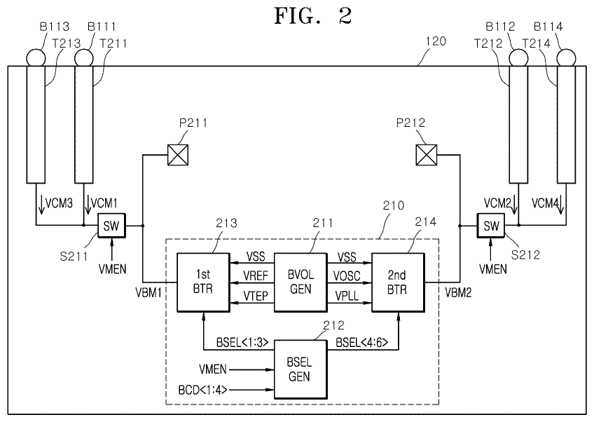

FIG. 2 illustrates a base die 120 according to an embodiment of the present disclosure, for example, as shown in FIG. 1.

As shown in FIG. 2, the base die 120 includes a first through-via T211 connected to a first micro-bump pad B111, a second through-via T212 connected to a second micro-bump pad B112, a third through-via T213 connected to a third micro-bump pad B113, a fourth through-via T214 connected to a fourth micro-bump pad B114, a first voltage monitoring pad P211, a second voltage monitoring pad P212, a first base switch S211, a second base switch S212, and a base voltage control circuit 210.

The first micro-bump pad B111, the second micro-bump pad B112, the third micro-bump pad B113, and the fourth micro-bump pad B114 are disposed on the base die 120 and configured, for example, as very small-sized bump pads used to stack a first core die 121-1 over the base die 120 as shown in FIG. 1.

The first through-via T211 receives a first core monitoring voltage VCM1 from the first core die 121-1. The second through-via T212 receives a second core monitoring voltage VCM2 from the first core die 121-1. The third through-via T213 receives a third core monitoring voltage VCM3 from a second core die 121-2 in FIG. 1. The fourth through-via T214 receives a fourth core monitoring voltage VCM4 from the second core die 121-2.

The first base switch S211 is connected between the first voltage monitoring pad P211 and a node connected to the first through via 211 and the third through via T213. The first base switch S211 outputs one of the first core monitoring voltage VCM1 and the third core monitoring voltage VCM3 to the first voltage monitoring pad P211 based on a voltage monitoring enable signal VMEN. The first base switch S211 prevents connection of the first through-via T211, the third through-via T213, and the first voltage monitoring pad P211 when the voltage monitoring enable signal VMEN is disabled. The first base switch S211 outputs one of the first core monitoring voltage VCM1 and the third core monitoring voltage VCM3 to the first voltage monitoring pad P211 when the voltage monitoring enable signal VMEN is enabled.

The second base switch S212 is connected between the second voltage monitoring pad P212 and a node connected to the second through-via 212 and the fourth through-via T214. The second base switch S212 outputs one of the second core monitoring voltage VCM2 and the fourth core monitoring voltage VCM4 to the second voltage monitoring pad P212 based on the voltage monitoring enable signal VMEN. The second base switch S212 prevents connection of the second through-via T212, the fourth through-via T214, and the second voltage monitoring pad P212 when the voltage monitoring enable signal VMEN is disabled. The second base switch S212 outputs one of the second core monitoring voltage VCM2 and the fourth core monitoring voltage VCM4 to the second voltage monitoring pad P212 when the voltage monitoring enable signal VMEN is enabled.

The base voltage control circuit 210 includes a base voltage generation circuit 211, a base selection signal generation circuit 212, a first base selection transmission circuit 213, and a second base selection transmission circuit 214.

The base voltage generation circuit 211 outputs ground voltage VSS and power supply voltage VDD. The base voltage generation circuit 211 generates a reference voltage VREF, a temperature voltage VTEP, a cyclic voltage VOSC, and a PLL voltage VPLL. The base voltage generation circuit 211 generates the reference voltage VREF, the temperature voltage VTEP, the cyclic voltage VOSC, and the PLL voltage VPLL at a lower voltage level than the voltage level of the power supply voltage VDD. The base voltage generation circuit 211 divides the power supply voltage VDD to generate the reference voltage VREF, the temperature voltage VTEP, the cyclic voltage VOSC, and the PLL voltage VPLL. The reference voltage VREF is used as a voltage that determines a logic high level and a logic low level of data and as a voltage used as a reference when performing a comparison operation in an internal circuit. The temperature voltage VTEP is used as a voltage supplied to a temperature sensor provided within the memory device 17. The cyclic voltage VOSC is used as a voltage supplied to an oscillator provided within the memory device 17. The PLL voltage VPLL is used as a voltage supplied to a phase-locked loop PLL circuit provided within the memory device 17. The base voltage generation circuit 211 is configured to generates internal voltages such as the reference voltage VREF, the temperature voltage VTEP, the cyclic voltage VOSC, and the PLL voltage VPLL, and may be configured to generate various other internal voltages depending on the embodiment.

The base selection signal generation circuit 212 generates first to sixth base selection signals BSEL<1:6> based on the voltage monitoring enable signal VMEN and first to fourth base voltage codes BCD<1:4>. The base selection signal generation circuit 212 generates the first base selection signal BSEL<1> and the fourth base selection signal BSEL<4> as enabled when the voltage monitoring enable signal VMEN is disabled. The base selection signal generation circuit 212 generates the second and third base selection signals BSEL<2:3> and the fifth and sixth base selection signals BSEL<5:6> based on the first to fourth base voltage codes BCD<1:4>. When monitoring voltages for the base die 120, the base selection signal generation circuit 212 outputs the first base voltage code BCD<1> as the second base selection signal BSEL<2>, outputs the second base voltage code BCD<2> as the third base selection signal BSEL<3>, outputs the third base voltage code BCD<3> as the fifth base selection signal BSEL<5>, and outputs the fourth base voltage code BCD<4> as the sixth base selection signal BSEL<6>. The first base voltage code BCD<1> is a signal enabled to monitor a voltage level of the reference voltage VREF, the second base voltage code BCD<2> is a signal enabled to monitor the voltage level of the temperature voltage VTEP, the third base voltage code BCD<3> is a signal enabled to monitor the voltage level of the cyclic voltage VOSC, and the fourth base voltage code BCD<4> is a signal enabled to monitor the voltage level of the PLL voltage VPLL.

The first base selection transmission circuit 213 generates a first base monitoring voltage VBM1 from one of the ground voltage VSS, the reference voltage VREF, and the temperature voltage VTEP based on the first to third base selection signals BSEL<1:3>. The first base selection transmission circuit 213 generates the first base monitoring voltage VBM1 from the ground voltage VSS when the first base selection signal BSEL<1> is enabled. The first base selection transmission circuit 213 generates the first base monitoring voltage VBM1 from the reference voltage VREF when the second base selection signal BSEL<2> is enabled. The first base selection transmission circuit 213 generates the first base monitoring voltage VBM1 from the temperature voltage VTEP when the third base selection signal BSEL<3> is enabled. The first base selection transmission circuit 213 outputs the first base monitoring voltage VBM1 to the first voltage monitoring pad P211.

The second base selection transmission circuit 214 generates a second base monitoring voltage VBM2 from one of the ground voltage VSS, the cyclic voltage VOSC, and the PLL voltage VPLL based on the fourth to sixth base selection signals BSEL<4:6>. The second base selection transmission circuit 214 generates the second base monitoring voltage VBM2 from the ground voltage VSS when the fourth base selection signal BSEL<4> is enabled. The second base selection transmission circuit 214 generates the second base monitoring voltage VBM2 from the cyclic voltage VOSC when the fifth base selection signal BSEL<5> is enabled. The second base selection transmission circuit 214 generates the second base monitoring voltage VBM2 from the PLL voltage VPLL when the sixth base selection signal BSEL<6> is enabled. The second base selection transmission circuit 214 outputs the second base monitoring voltage VBM2 to the second monitoring pad P212.

The base voltage control circuit 210 generates the first base monitoring voltage VBM1 and the second base monitoring voltage VBM2 from the ground voltage VSS, the reference voltage VREF, the temperature voltage VTEP, the cyclic voltage VOSC, and the PLL voltage VPLL based on the voltage monitoring enable signal VMEN and the first to fourth base voltage codes BCD<1:4>. The base voltage control circuit 210 generates the first base monitoring voltage VBM1 from one of the ground voltage VSS, the reference voltage VREF, and the temperature voltage VTEP based on the voltage monitoring enable signal VMEN and the first and second base voltage codes BCD<1:2>. The base voltage control circuit 210 outputs the first base monitoring voltage VBM1 to the first voltage monitoring pad P211. The base voltage control circuit 210 generates the second base monitoring voltage VBM2 from one of the ground voltage VSS, the cyclic voltage VOSC, and the PLL voltage VPLL based on the voltage monitoring enable signal VMEN and the third and fourth base voltage codes BCD<3:4>. The base voltage control circuit 210 outputs the second base monitoring voltage VBM2 to the second voltage monitoring pad P212.

The base die 120 monitors the first core monitoring voltage VCM1 output from the first core die 121-1 through the first voltage monitoring pad P211. The base die 120 monitors the second core monitoring voltage VCM2 output from the first core die 121-1 through the second voltage monitoring pad P212. The base die 120 monitors the third core monitoring voltage VCM3 output from the second core die 121-2 through the first voltage monitoring pad P211. The base die 120 monitors the fourth core monitoring voltage VCM4 output from the second core die 121-2 through the second voltage monitoring pad P212. The base die 120 monitors core monitoring voltages output from a plurality of core dies 121-1 to 121-L in FIG. 1 during a voltage monitoring operation. The base die 120 includes a circuit capable of monitoring the core monitoring voltages applied to the voltage monitoring pads during the voltage monitoring operation according to an embodiment. According to an embodiment, the processor 19 monitors the core monitoring voltages applied to the voltage monitoring pads during the voltage monitoring operation.

The base die 120 monitors the first core monitoring voltage VCM1 and the second core monitoring voltage VCM2 output from the first core die 121-1 in an embodiment. According to an embodiment, the base die 120 receives and monitors the core monitoring voltage generated when generating one of the first core monitoring voltage VCM1 and the second core monitoring voltage VCM2 in the first core die 121-1 as the monitored first core monitoring voltage. In this example, the monitored first core monitoring voltage includes a voltage generated from one of the first core monitoring voltage VCM1 and the second core monitoring voltage VCM2.

The base die 120 monitors the third core monitoring voltage VCM3 and the fourth core monitoring voltage VCM4 output from the second core die 121-2 in an embodiment. According to an embodiment, the base die 120 receives and monitors the core monitoring voltage generated when generating one of the third core monitoring voltage VCM3 and the fourth core monitoring voltage VCM4 in the second core die 121-2 as the monitored second core monitoring voltage. In this example, the monitored second core monitoring voltage includes a voltage generated from one of the third core monitoring voltage VCM3 and the fourth core monitoring voltage VCM4.

The base die 120 monitors the first core monitoring voltage VCM1 and the second core monitoring voltage VCM2 output from the first core die 121-1 and the third core monitoring voltage VCM3 and the fourth core monitoring voltage VCM4 output from the second core die 121-2 in an embodiment. Alternatively, the base die 120 may monitor the core monitoring voltages output from any or all of the plurality of core dies.

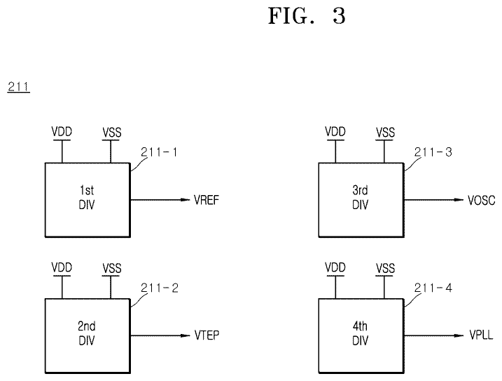

FIG. 3 illustrates a base voltage generation circuit 211 according to an embodiment of the present disclosure, for example, as shown in FIG. 2.

As shown in FIG. 3, the base voltage generation circuit 211 includes a first voltage dividing circuit 211-1, a second voltage dividing circuit 211-2, a third voltage dividing circuit 211-3, and a fourth voltage dividing circuit 211-4.

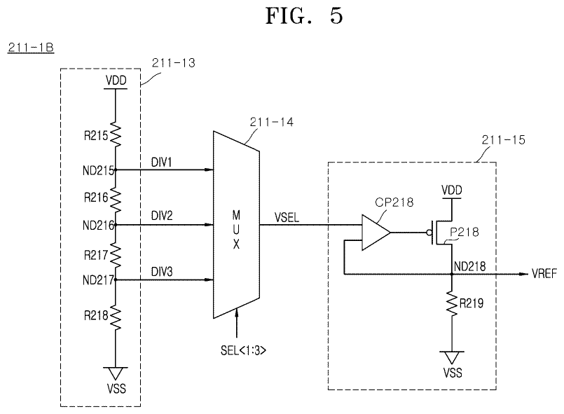

The first voltage dividing circuit 211-1 receives power supply voltage VDD and ground voltage VSS and generates a reference voltage VREF. The first voltage dividing circuit 211-1 divides the power supply voltage VDD to generate the reference voltage VREF. To control a voltage level of the reference voltage VREF, the first voltage dividing circuit 211-1 compares the reference voltage VREF with a selection voltage, for example, VSEL in FIG. 5, generated by dividing the power supply voltage VDD.

The second voltage dividing circuit 211-2 receives the power supply voltage VDD and the ground voltage VSS and generates a temperature voltage VTEP. The second voltage dividing circuit 211-2 divides the power supply voltage VDD to generate the temperature voltage VTEP. To control a voltage level of the temperature voltage VTEP, the second voltage dividing circuit 211-2 compares the temperature voltage VTEP with a predetermined voltage (not shown) generated by dividing the power supply voltage VDD.

The third voltage dividing circuit 211-3 receives the power supply voltage VDD and the ground voltage VSS and generates a cyclic voltage VOSC. The third voltage dividing circuit 211-3 divides the power supply voltage VDD to generate the cyclic voltage VOSC. To control a voltage level of the cyclic voltage VOSC, the third voltage dividing circuit 211-2 compares the cyclic voltage VOSC with a predetermined voltage (not shown) generated by dividing the power supply voltage VDD.

The fourth voltage dividing circuit 211-4 receives the power supply voltage VDD and the ground voltage VSS and generates a PLL voltage VPLL. The fourth voltage dividing circuit 211-4 divides the power supply voltage VDD to generate the PLL voltage VPLL. To control a voltage level of the PLL voltage VPLL, the fourth voltage dividing circuit 211-4 compares the PLL voltage VPLL with a predetermined voltage (not shown) generated by dividing the power supply voltage VDD.

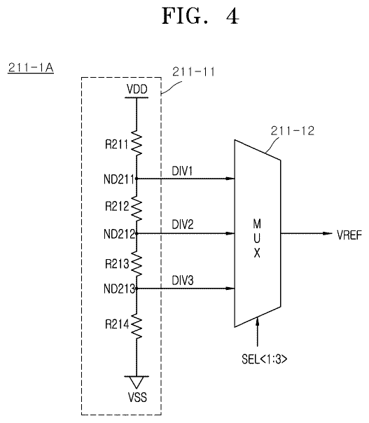

FIG. 4 illustrates an example 211-1A of a first voltage dividing circuit according to an embodiment of the present disclosure, for example, as shown in FIG. 3. The first voltage dividing circuit 211-1A includes a division voltage generation circuit 211-11 and a multiplexer 211-12.

The division voltage generation circuit 211-11 includes a resistor R211 disposed between a power supply voltage VDD and a mode ND211, a resistor R212 disposed between the node ND211 and a node ND212, a resistor R213 disposed the node ND212 and a node ND213, and a resistor R214 disposed between the node ND213 and ground voltage VSS. The division voltage generation circuit 211-11 divides the power supply voltage VDD according to resistances of the resistors R211, R212, R213, and R214 disposed between the power supply voltage VDD and the ground voltage VSS to generate a first division voltage DIV1, a second division voltage DIV2, and a third division voltage DIV3. The division voltage generation circuit 211-11 divides the power supply voltage VDD to generate the first division voltage DIV1, the second division voltage DIV2, and the third division voltage DIV3 having sequentially decreased voltage levels. The division voltage generation circuit 211-11 divides the power supply voltage VDD to generate the first division voltage DIV1, the second division voltage DIV2, and the third division voltage DIV3 having predetermined voltage levels. The first division voltage DIV1, the second division voltage DIV2, and the third division voltage DIV3 may be at various different voltage levels depending on the resistances of the resistors R211, R212, R213, and R214.

The multiplexer 211-12 generates a reference voltage VREF from one of the first division voltage DIV1, the second division voltage DIV2, and the third division voltage DIV3 based on first to third selection signals SEL<1:3>. The multiplexer 211-12 outputs the first division voltage DIV1 as the reference voltage VREF when the first selection signal SEL<1> is enabled. The multiplexer 211-12 outputs the second division voltage DIV2 as the reference voltage VREF when the second selection signal SEL<2> is enabled. The multiplexer 211-12 outputs the third division voltage DIV3 as the reference voltage VREF when the third selection signal SEL<3> is enabled. The first to third selection signals SEL<1:3> may be input from the processor 19 shown in FIG. 1.

The second voltage dividing circuit 211-2, the third voltage dividing circuit 211-3, and the fourth voltage dividing circuit 211-4 shown in FIG. 3 are implemented with similar circuits such as in the first voltage dividing circuit 211-1A shown in FIG. 4 and perform similar operations, except that the voltage dividing circuits 211-2 to 211-4 generate different voltages as described with reference to FIG. 3.

FIG. 5 illustrates an example 211-1B of a first voltage dividing circuit according to an embodiment of the present disclosure, for example, as shown in FIG. 3. The first voltage dividing circuit 2 11-1B includes a division voltage generation circuit 211-13, a multiplexer 211-14, and a comparison circuit 211-15.

The division voltage generation circuit 211-13 includes a resistor R215 disposed between a power supply voltage VDD and a mode ND215, a resistor R216 disposed between the node ND215 and a node ND216, a resistor R217 disposed between the node ND216 and a node ND217, and a resistor R218 disposed between the node ND217 and ground voltage VSS. The division voltage generation circuit 211-13 divides the power supply voltage VDD according to resistances of the resistors R215, R216, R217, and R218 disposed between the power supply voltage VDD and the ground voltage VSS to generate a first division voltage DIV1, a second division voltage DIV2, and a third division voltage DIV3. The division voltage generation circuit 211-13 divides the power supply voltage VDD to generate the first division voltage DIV1, the second division voltage DIV2, and the third division voltage DIV3 having sequentially decreased voltage levels. The division voltage generation circuit 211-13 divides the power supply voltage VDD to generate the first division voltage DIV1, the second division voltage DIV2, and the third division voltage DIV3 having predetermined voltage levels. The first division voltage DIV1, the second division voltage DIV2, and the third division voltage DIV3 may be at various different voltage levels depending on the resistances of the resistors R215, R216, R217, and R218.

The multiplexer 211-14 generates a selection voltage VSEL from one of the first division voltage DIV1, the second division voltage DIV2, and the third division voltage DIV3 based on first to third selection signals SEL<1:3>. The multiplexer 211-14 outputs the first division voltage DIV1 as the selection voltage VSEL when the first selection signal SEL<1> is enabled. The multiplexer 211-14 outputs the second division voltage DIV2 as the selection voltage VSEL when the second selection signal SEL<2> is enabled. The multiplexer 211-14 outputs the third division voltage DIV3 as the selection voltage VSEL when the third selection signal SEL<3> is enabled. The first to third selection signals SEL<1:3> may be input from the processor 19 shown in FIG. 1.

The comparison circuit 211-15 includes a comparator CP218, a PMOS transistor P218, and a resistor R219. The comparator CP218 compares the selection voltage VSEL with a reference voltage VREF to generate an output signal. The comparator CP218 generates the output signal at a logic low level when a voltage level of the reference voltage VREF is lower than the voltage level of the selection voltage VSEL. The comparator CP218 generates the output signal at a logic high level when the voltage level of the reference voltage VREF is equal to the voltage level of the selection voltage VSEL. The comparator CP218 generates the output signal at a logic high level when the voltage level of the reference voltage VREF is higher than the voltage level of the selection voltage VSEL. The PMOS transistor P218 is disposed between the power supply voltage VDD and the node ND218 where the reference voltage VREF is output. The PMOS transistor P218 increases the voltage level of the reference voltage VREF by driving the node ND218 to the power supply voltage VDD when the output signal of the comparator CP218 is at a logic low level. The PMOS transistor P218 does not drive the node ND218 when the output signal of the comparator CP218 is at a logic high level. The PMOS transistor P218 can be replaced by NMOS transistor. In an embodiment, when the PMOS transistor P218 is replaced with an NMOS transistor, the NMOS transistor drives the node ND218 to the power supply voltage VDD when the output signal of the comparator CP218 is at a logic high level. The resistor R219 is disposed between the node ND218 and the ground voltage VSS. The voltage level of the reference voltage VREF is determined according to a resistance of the resistor R219.

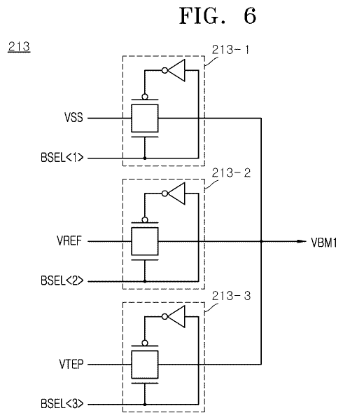

FIG. 6 illustrates an example of a first base selection transmission circuit 213 according to an embodiment of the present disclosure, for example, as shown in FIG. 2. The first base selection transmission circuit 213 includes a first base transmission circuit 213-1, a second base transmission circuit 213-2, and a third base transmission circuit 213-3.

The first base transmission circuit 213-1 generates a first base monitoring voltage VBM1 from ground voltage VSS based on a first selection signal BSEL<1>. The first base transmission circuit 213-1 outputs the ground voltage VSS as the first base monitoring voltage VBM1 when the first base selection signal BSEL<1> is enabled at a logic high level. The first base transmission circuit 213-1 prevents output of the ground voltage VSS when the first base selection signal BSEL<1> is disabled at a logic low level.

The second base transmission circuit 213-2 generates the first base monitoring voltage VBM1 from the reference voltage VREF based on a second base selection signal BSEL<2>. The second base transmission circuit 213-2 outputs the reference voltage VREF as the first base monitoring voltage VBM1 when the second base selection signal BSEL<2> is enabled. The second base transmission circuit 213-2 prevents output of the reference voltage VREF when the second base selection signal BSEL<2> is disabled.

The third base transmission circuit 213-3 generates the first base monitoring voltage VBM1 from the temperature voltage VTEP based on a third base selection signal BSEL<3>. The third base transmission circuit 213-3 outputs the temperature voltage VTEP as the first based monitoring voltage VBM1 when the third base selection signal BSEL<3> is enabled. The third base transmission circuit 213-3 prevents output of the temperature voltage VTEP when the third base selection signal BSEL<3> is disabled.

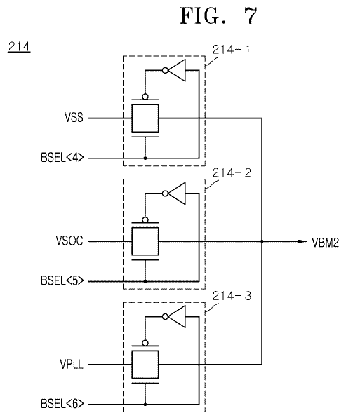

FIG. 7 illustrates an example of a second base selection transmission circuit 214 according to an embodiment of the present disclosure, for example, as shown in FIG. 2. The second base selection transmission circuit 214 includes a fourth base transmission circuit 214-1, a fifth base transmission circuit 214-2, and a sixth base transmission circuit 214-3.

The fourth base transmission circuit 214-1 generates a second base monitoring voltage VBM2 from ground voltage VSS based on a fourth base selection signal BSEL<4>. The fourth base transmission circuit 214-1 outputs the ground voltage VSS as the second base monitoring voltage VBM2 when the fourth base selection signal BSEL<4> is enabled. The fourth base transmission circuit 214-1 prevents output of the ground voltage VSS when the fourth base selection signal BSEL<4> is disabled.

The fifth base transmission circuit 214-2 generates the second base monitoring voltage VBM2 from a cyclic voltage VOSC based on a fifth base selection signal BSEL<5>. The fifth base transmission circuit 214-2 outputs the cyclic voltage VOSC as the second base monitoring voltage VBM2 when the fifth base selection signal BSEL<5> is enabled. The fifth base transmission circuit 214-2 prevents output of the cyclic voltage VOSC when the fifth base selection signal BSEL<5> is disabled.

The sixth base transmission circuit 214-3 generates the second base monitoring voltage VBM2 from a PLL voltage VPLL based on a sixth base selection signal BSEL<6>. The sixth base transmission circuit 214-3 outputs the PLL voltage VPLL as the second base monitoring voltage VBM2 when the sixth base selection signal BSEL<6> is enabled. The sixth base transmission circuit 214-3 prevents output of the PLL voltage VPLL when the sixth base selection signal BSEL<6> is disabled.

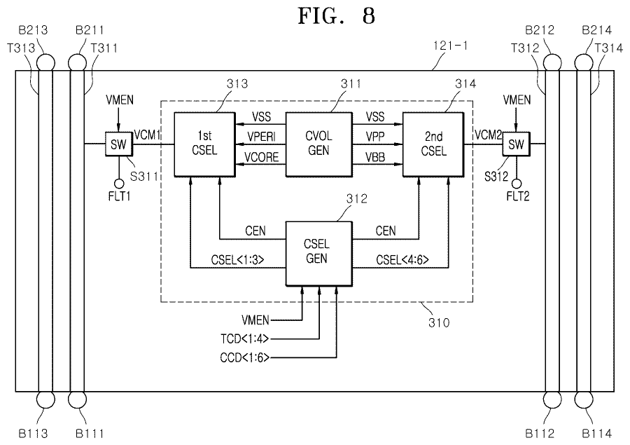

FIG. 8 illustrates a first core die 121-1 according to an embodiment of the present disclosure, for example, as shown in FIG. 1. The first core die 121-1 includes a fifth through-via T311 connected between a first micro-bump pad B111 and a fifth micro-bump pad B211, a sixth through-via T312 connected between a second micro-bump pad B112 and a sixth micro-bump pad B212, a seventh through-via T313 connected between a third micro-bump pad B113 and a seventh micro-bump pad B213, an eighth through-via T314 connected between a fourth micro-bump pad B114 and an eighth micro-bump pad B214, a first core switch S311, a second core switch S312, and a core voltage control circuit 310.

The fifth micro-bump pad B211, the sixth micro-bump pad B212, the seventh micro-bump pad B213, and the eighth micro-bump pad B214 are positioned on the first core die 121-1 and may be very small-sized bump pads used to stack the second core die 121-2 over the first core die 121-1.

The fifth through-via T311 receives the first core monitoring voltage VCM1 from the core voltage control circuit 310. The sixth through-via T312 receives the second core monitoring voltage VCM2 from the core voltage control circuit 310. The seventh through-via T313 receives the third core monitoring voltage VCM3 from the second core die 121-2. The eighth through-via T314 receives the fourth core monitoring voltage VCM4 from the second core die 121-2.

The first core switch S311 is connected to the fifth through-via T311, the core voltage control circuit 310, and a first floating node FLT1. The first core switch S311 controls connection between the fifth through-via T311, the core voltage control circuit 310, and the first floating node FLT1 based on a voltage monitoring enable signal VMEN. The first core switch S311 outputs the first core monitoring voltage VCM1 to the fifth through-via T311 based on the voltage monitoring enable signal VMEN. The first core switch S311 prevents connection between the fifth through-via T311 and the core voltage control circuit 310 when the voltage monitoring enable signal VMEN is disabled. The first core switch S311 connects the fifth through-via T311 to the first floating node FLT1 when the voltage monitoring enable signal VMEN is enabled. The first core switch S311 outputs the first core monitoring voltage VCM1 to the fifth through-via T311 when the voltage monitoring enable signal VMEN is enabled. The first floating node FLT1 may be in a floating state in which connection outside the memory device 17 is prevented.

The second core switch S312 is connected to the sixth through-via T312, the core voltage control circuit 310, and a second floating node FLT2. The second core switch S312 controls connection between the sixth through-via T312, the core voltage control circuit 310, and the second floating node FLT2 based on the voltage monitoring enable signal VMEN. The second core switch S312 outputs the second core monitoring voltage VCM2 to the sixth through-via T312 based on the voltage monitoring enable signal VMEN. The second core switch S312 prevents connection between the sixth through-via T312 and the core voltage control circuit 310 when the voltage monitoring enable signal VMEN is disabled. The second core switch S312 connects the sixth through-via T312 to the second floating node FLT2 when the voltage monitoring enable signal VMEN is enabled. The second core switch S312 outputs the second core monitoring voltage VCM2 to the sixth through-via T312 when the voltage monitoring enable signal VMEN is enabled. The second floating node FLT2 may be in a floating state in which connection outside the memory device 17 is prevented.

The core voltage control circuit 310 includes a core voltage generation circuit 311, a core selection signal generation circuit 312, a first core selection transmission circuit 313, and a second core selection transmission circuit 314.

The core voltage generation circuit 311 receives ground voltage VSS and power supply voltage VDD. The core voltage generation circuit 311 generates the peripheral voltage VPERI, the core voltage VCORE, a high voltage VPP, and a low voltage VBB. The core voltage generation circuit 311 generates the peripheral voltage VPERI and the core voltage VCORE at a lower voltage level than the voltage level of the power supply voltage VDD. The core voltage generation circuit 311 generates the high voltage VPP at a higher voltage level than the power supply voltage VDD and generates the low voltage VBB at a lower voltage level than the voltage level of the ground voltage VSS. The core voltage generation circuit 311 divides the power supply voltage VDD to generate the peripheral voltage VPERI and the core voltage VCORE. The core voltage generation circuit 311 generates a voltage higher than the power supply voltage VDD to generate the high voltage VPP, for example, by utilizing a charge pump circuit. The core voltage generation circuit 311 generates a voltage lower than the ground voltage VSS to generate the low voltage VBB, for example, by utilizing a charge pump circuit. The peripheral voltage VPERI is a voltage used in a peripheral region (not shown) that controls a core region (not shown) of the first core die 121-1. The core voltage VCORE is a voltage used in the core region including memory cells. The high voltage VPP may be a voltage that activates word lines (not shown) included in the core region. The low voltage VBB may be a voltage supplied to a base of each transistor used in the core region and the peripheral region, for example, to bias the transistor. The core voltage generation circuit 311 generates internal voltages such as the peripheral voltage VPERI, the core voltage VCORE, the high voltage VPP, and the low voltage VBB, and may generate various other internal voltages depending on the embodiment.

The core selection signal generation circuit 312 generates a core enable signal CEN based on the voltage monitoring enable signal VMEN and first to fourth target codes TCD<1:4>. The core selection signal generation circuit 312 generates first to sixth core selection signals CSEL<1:6> based on first to sixth core voltage codes CCD<1:6>. The core selection signal generation circuit 312 generates the core enable signal CEN as disabled when the voltage monitoring enable signal VMEN is enabled. The core selection signal generation circuit 312 generates the core enable signal CEN as enabled when the voltage monitoring enable signal VMEN is enabled and the first to fourth target codes TCD<1:4> are input with a first logic level combination. The core selection signal generation circuit 312 outputs the first to sixth core voltage codes CCD<1:6> as the first to sixth core selection signals CSEL<1:6>.

The first core selection transmission circuit 313 generates the first core monitoring voltage VCM1 from one of the ground voltage VSS, the peripheral voltage VPERI, and the core voltage VCORE based on the core enable signal CEN and the first to third core selection signals CSEL<1:3>. The first core selection transmission circuit 313 generates the first core monitoring voltage VCM1 from the ground voltage VSS when the core enable signal CEN is enabled and the first core selection signal CSEL<1> is enabled. The first core selection transmission circuit 313 generates the first core monitoring voltage VCM1 from the peripheral voltage VPERI when the core enable signal CEN is enabled and the second core selection signal CSEL<2> is enabled. The first core selection transmission circuit 313 generates the first core monitoring voltage VCM1 from the core voltage VCORE when the core enable signal CEN is enabled and the third core selection signal CSEL<3> is enabled. The first core selection transmission circuit 313 outputs the first core monitoring voltage VCM1 to the first core switch S311.

The second core selection transmission circuit 314 generates the second core monitoring voltage VCM2 from one of the ground voltage VSS, the high voltage VPP, and the low voltage VBB based on the core enable signal CEN and the fourth to sixth core selection signals CSEL<4:6>. The second core selection transmission circuit 314 generates the second core monitoring voltage VCM2 from the ground voltage VSS when the core enable signal CEN is enabled and the fourth core selection signal CSEL<4> is enabled. The second core selection transmission circuit 314 generates the second core monitoring voltage VCM2 from the high voltage VPP when the core enable signal CEN is enabled and the fifth core selection signal CSEL<5> is enabled. The second core selection transmission circuit 314 generates the second core monitoring voltage VCM2 from the low voltage VBB when the core enable signal CEN is enabled and the sixth core selection signal CSEL<6> is enabled. The second core selection transmission circuit 314 outputs the second core monitoring voltage VCM2 to the second core switch S312.

The core voltage control circuit 310 generates the first core monitoring voltage VCM1 and the second core monitoring voltage VCM2 from the ground voltage VSS, the peripheral voltage VPERI, the core voltage VCORE, the high voltage VPP, and the low voltage VBB based on the voltage monitoring enable signal VMEN, the first to fourth target codes TCD<1:4>, and the first to sixth core voltage codes CCD<1:6>. The core voltage control circuit 310 generates the first core monitoring voltage VCM1 from one of the ground voltage VSS, the peripheral voltage VPERI, and the core voltage VCORE based on the voltage monitoring enable signal VMEN, the first to fourth target codes TCD<1:4>, and the first to third core voltage codes CCD<1:3>. The core voltage control circuit 310 outputs the first core monitoring voltage VCM1 to the first core switch S311. The core voltage control circuit 310 generates the second core monitoring voltage VCM2 from one of the ground voltage VSS, the high voltage VPP, and the low voltage VBB based on the voltage monitoring enable signal VMEN, the first to fourth target codes TCD<1:4>, and the fourth to sixth core voltage codes CCD<4:6>. The core voltage control circuit 310 outputs the second core monitoring voltage VCM2 to the second core switch S312.

The first core die 121-1 is stacked over the base die 120 in FIG. 1 with the first micro-bump pad B111, the second micro-bump pad B112, the third micro-bump pad B113, and the fourth micro-bump pad B114 between the first core die 121-1 and the base die 120. The first core die 121-1 is electrically connected to the base die 120 using the fifth through-via T311, the sixth through-via T312, the seventh through-via T313, and the eighth through-via T314. The first core die 121-1 outputs the first core monitoring voltage VCM1 to the first voltage monitoring pad P211 through the fifth through-via T311 after connecting the fifth through-via T311 to the ground voltage VSS upon entering the voltage monitoring operation. The first core die 121-1 outputs the second core monitoring voltage VCM2 to the second voltage monitoring pad P212 through the sixth through-via T312 after connecting the sixth through-via T312 to the ground voltage VSS upon entering the voltage monitoring operation. The first core die 121-1 outputs the third core monitoring voltage VCM3 output from the second core die 121-2 to the first voltage monitoring pad P211 through the seventh through via T313 during the voltage monitoring operation. The first core die 121-1 prevents generation of the first core monitoring voltage VCM1 when the third core monitoring voltage VCM3 is output from the second core die 121-2 during the voltage monitoring operation. The first core die 121-1 outputs the fourth core monitoring voltage VCM4 output from the second core die 121-2 to the second voltage monitoring pad P212 through the eighth through-via T314 during the voltage monitoring operation. The first core die 121-1 prevents generation of the second core monitoring voltage VCM2 when the fourth core monitoring voltage VCM4 is output from the second core die 121-2 during the voltage monitoring operation.

The plurality of core dies 121-2 to 121-L shown in FIG. 1 have a similar configuration to the configuration of the first core die 121-1 shown in FIG. 8 and perform similar operations.

The first core die 121-1 shown in FIG. 8 includes the fifth through-via T311, the sixth through-via T312, the seventh through-via T313, and the eighth through-via T314, and may include a plurality of through-vias to output a plurality of core monitoring voltages from the plurality of core dies 121-3 to 121-L to the base die 120.

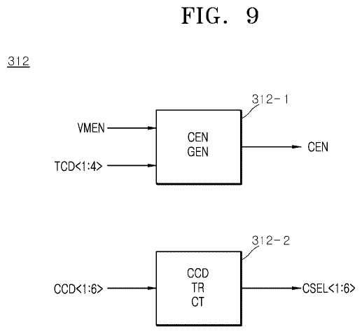

FIG. 9 illustrates a core selection signal generation circuit 312 according to an embodiment of the present disclosure, for example, as shown in FIG. 8. The core selection signal generation circuit 312 includes a core enable signal generation circuit 312-1 and a core voltage code transmission circuit 312-2.

The core enable signal generation circuit 312-1 generates a core enable signal CEN based on a voltage monitoring enable signal VMEN and first to fourth target codes TCD<1:4>. The core enable signal generation circuit 312-1 generates the core enable signal CEN as disabled when the voltage monitoring enable signal VMEN is enabled. The core enable signal generation circuit 312-1 generates the core enable signal CEN as enabled when the voltage monitoring enable signal VMEN is enabled and the first to fourth target codes TCD<1:4> are input with a first logic level combination. The first to fourth target codes CD<1:4> are signals that select a plurality of core dies 121-1 to 121-16, for example, as shown in FIG. 1. For example, when the first to fourth target codes TCD<1:4> include a first logic level combination, a voltage monitoring operation for the first core die 121-1 is performed. When the first to fourth target codes TCD<1:4> include a second logic level combination, a voltage monitoring operation for the second core die 121-2 is performed. When the first to fourth target codes TCD<1:4> include a sixteenth logic level combination, a voltage monitoring operation for the sixteenth core die 121-16 is performed.

The core voltage code transmission circuit 312-2 outputs first to sixth core selection signals CSEL<1:6>. The core voltage code transmission circuit 312-2 buffers the first to sixth core voltage codes CCD<1:6> to generate the first to sixth core selection signals CSEL<1:6>. The first to sixth core voltage codes CCD<1:6> are signals that select ground voltage VSS, the peripheral voltage VPERI, the core voltage VCORE, the high voltage VPP, and the low voltage VBB generated by the core voltage generation circuit 311 in FIG. 8. The first and second core voltage codes CCD<1:2> are signals that select the ground voltage VSS. The third core voltage code CCD<3> is a signal that selects the peripheral voltage VPERI generated by the core voltage generation circuit 311. The fourth core voltage code CCD<4> is a signal that selects the core voltage VCORE generated by the core voltage generation circuit 311. The fifth core voltage code CCD<5> is a signal that selects the high voltage VPP generated by the core voltage generation circuit 311. The sixth core voltage code CCD<6> is a signal that selects the low voltage VBB generated by the core voltage generation circuit 311. The first to sixth core voltage codes CCD<1:6> may be input from the processor 19 shown in FIG. 1.

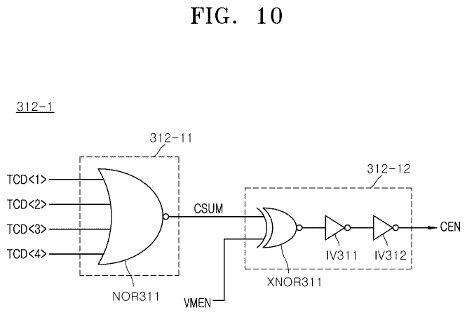

FIG. 10 illustrates a core enable signal generation circuit 312-1 according to an embodiment of the present disclosure, for example, as shown in FIG. 9. The core enable signal generation circuit 312-1 includes a composite signal generation circuit 312-11 and a logic circuit 312-12.

The composite signal generation circuit 312-11 includes a NOR gate NOR311. The composite signal generation circuit 312-11 generates a composite signal CSUM at a logic high level when first to fourth target codes TCD<1:4> include a first logic level combination. The composite signal generation circuit 312-11 generates the composite signal CSUM at a logic high level when the first target code TCD<1> is at a logic low level, the second target code TCD<2> is at a logic low level, the third target code TCD<3> is at a logic low level, and the fourth target code TCD<4> is at a logic low level. When the first to fourth target codes TCD<1:4> are in the first logic level combination, the first target code TCD<1> is at a logic low level, the second target code TCD<2> is at a logic low level, the third target code TCD<3> is at a logic low level, and the fourth target code TCD<4> is at a logic low level.

A composite signal generation circuit (not shown) included in the second core die 121-2 shown in FIG. 1 generates the composite signal CSUM at a logic high level when the first to fourth target codes TCD<1:4> are in a second logic level combination. When the first to fourth target codes TCD<1:4> are in the second logic level combination, the first target code TCD<1> is at a logic high level, the second target code TCD<2> is at a logic low level, the third target code TCD<3> is at a logic low level, and the fourth target code TCD<4> is at a logic low level.

A composite signal generation circuit (not shown) included in a sixteenth core die 121-16 shown in FIG. 1 generates the composite signal CSUM at a logic high level when the first to fourth target codes TCD<1:4> are in a sixteenth logic level combination. When the first to fourth target codes TCD<1:4> are in the sixteenth logic level combination, the first target code TCD<1> is at a logic high level, the second target code TCD<2> is at a logic high level, the third target code TCD<3> is at a logic high level, and the fourth target code TCD<4> is at a logic high level.

The logic circuit 312-12 includes an exclusive NOR gate XNOR311 and inverters IV311 and IV312.

The logic circuit 312-12 generates a core enable signal CEN based on the composite signal CSUM and a voltage monitoring enable signal VMEN. The logic circuit 312-12 generates the core enable signal CEN disabled at a logic low level when the composite signal CSUM is disabled at a logic low level and the voltage monitoring enable signal VMEN is enabled at a logic high level. The logic circuit 312-12 generates the core enable signal CEN enabled at a logic high level when the composite signal CSUM is enabled at a logic high level and the voltage monitoring enable signal VMEN is enabled at a logic high level.

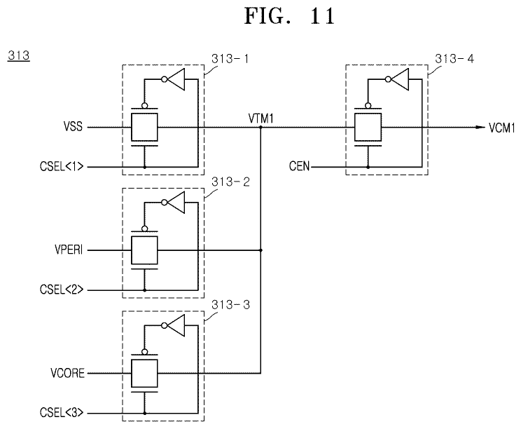

FIG. 11 illustrates a first core selection transmission circuit 313 according to an embodiment of the present disclosure, for example, as shown in FIG. 8. The first core selection transmission circuit 313 includes a first core transmission circuit 313-1, a second core transmission circuit 313-2, a third core transmission circuit 313-3, and a fourth core transmission circuit 313-4.

The first core transmission circuit 313-1 generates a first core transmission voltage VTM1 from ground voltage VSS based on a first core selection signal CSEL<1>. The first core transmission circuit 313-1 outputs the ground voltage VSS as the first core transmission voltage VTM1 when the first core selection signal CSEL<1> is enabled. The first core transmission circuit 313-1 prevents output of the ground voltage VSS when the first core selection signal CSEL<1> is disabled.

The second core transmission circuit 313-2 generates the first core transmission voltage VTM1 from the peripheral voltage VPERI based on a second core selection signal CSEL<2>. The second core transmission circuit 313-2 outputs the peripheral voltage VPERI as the first core transmission voltage VTM1 when the second core selection signal CSEL<2> is enabled. The second core transmission circuit 313-2 prevents output of the peripheral voltage VPERI when the second core selection signal CSEL<2> is disabled.

The third core transmission circuit 313-3 generates the first core transmission voltage VTM1 from the core voltage VCORE based on a third core selection signal CSEL<3>. The third core transmission circuit 313-3 outputs the core voltage VCORE as the first core transmission voltage VTM1 when the third core selection signal CSEL<3> is enabled. The third core transmission circuit 313-3 prevents output of the core voltage VCORE when the third core selection signal CSEL<3> is disabled.

The fourth core transmission circuit 313-4 generates the first core monitoring voltage VCM1 from the first core transmission voltage VTM1 based on a core enable signal CEN. The fourth core transmission circuit 313-4 outputs the first core transmission voltage VTM1 as the first core monitoring voltage VCM1 when the core enable signal CEN is enabled. The fourth core transmission circuit 313 prevents output of the first core transmission voltage VTM1 when the core enable signal CEN is disabled.

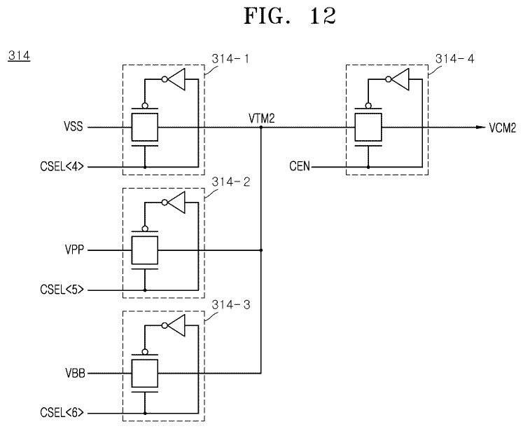

FIG. 12 illustrates a second core selection transmission circuit 314 according to an embodiment of the present disclosure, for example, as shown in FIG. 8. The second core selection transmission circuit 314 includes a fifth core transmission circuit 314-1, a sixth core transmission circuit 314-2, a seventh core transmission circuit 314-3, and an eighth core transmission circuit 314-4.

The fifth core transmission circuit 314-1 generates a second core transmission voltage VTM2 from ground voltage VSS based on a fourth core selection signal CSEL<4>. The fifth core transmission circuit 314-1 outputs the ground voltage VSS as the second core transmission voltage VTM2 when the fourth core selection signal CSEL<4> is enabled. The fifth core transmission circuit 314-1 prevents output of the ground voltage VSS when the fourth core selection signal CSEL<4> is disabled.

The sixth core transmission circuit 314-2 generates the second core transmission voltage VTM2 from a high voltage VPP based on a fifth core selection signal CSEL<5>. The sixth core transmission circuit 314-2 outputs the high voltage VPP as the second core transmission voltage VTM2 when the fifth core selection signal CSEL<5> is enabled. The sixth core transmission circuit 314-2 prevents output of the high voltage VPP when the fifth core selection signal CSEL<5> is disabled.

The seventh core transmission circuit 314-3 generates the second core transmission voltage VTM2 from the low voltage VBB based on a sixth core selection signal CSEL<6>. The sixth core transmission circuit 314-2 outputs the low voltage VBB as the second core transmission voltage VTM2 when the sixth core selection signal CSEL<6> is enabled. The sixth core transmission circuit 314-2 prevents output of the low voltage VBB when the sixth core selection signal CSEL<6> is disabled.

The eighth core transmission circuit 314-4 generates the second core monitoring voltage VCM2 from the second core transmission voltage VTM2 based on a core enable signal CEN. The eighth core transmission circuit 314-4 outputs the second core transmission voltage VTM2 as the second core monitoring voltage VCM2 when the core enable signal CEN is enabled. The eighth core transmission circuit 314-4 prevents output of the second core transmission voltage VTM2 when the core enable signal CEN is disabled.

According to an example of the present disclosure, a base die 120 and a plurality of core dies 121-1 to 121-L of a memory system 1 are stacked, for example, after connecting the through-vias to the ground voltage VSS before a voltage monitoring operation, thereby preventing through-via defects caused by charges accumulating in the through-vias. The memory system 1 monitors the internal voltage of a selected core die during the voltage monitoring operation after the base die 120 and the plurality of core dies 121-1 to 121-L are stacked. The memory system 1 generates an internal voltage higher than a power supply voltage VDD, referred to as a higher internal voltage, such as VPP, after the base die 120 and the plurality of core dies 121-1 to 121-L are stacked, voltage divides the higher internal voltage, and monitors the voltage-divided higher internal voltage. The memory system 1 generates a divided higher internal voltage by voltage division of the higher internal voltage and outputs the divided higher internal voltage using the through-vias, thereby preventing output of the higher internal voltage to the through-vias to protect the through-vias.

An operation of the memory system 1 according to an embodiment of the present disclosure is described with reference to FIG. 1 to FIG. 12. An operation performed before performing the voltage monitoring operation on the first core die 121-1 and the second core die 121-2 and the voltage monitoring operation performed on the first core die 121-1 are described as an example.

The first base switch S211 of the base die 120 outputs the first base monitoring voltage VBM1 at a voltage level of the ground voltage VSS to the first through-via T211 and the third through-via T213 prior to the voltage monitoring operation. The second base switch S212 outputs the second base monitoring voltage VBM2 at a voltage level of the ground voltage VSS to the second through-via T212 and the fourth through-via T214. Tus, the base die 120 connects the ground voltage VSS to the first through-via T211, the second through-via T212, the third through-via T213, and the fourth through-via T214.

The first core switch S311 of the first core die 121-1 outputs the first core monitoring voltage VCM1 at a voltage level of the ground voltage VSS to the fifth through-via T311. The second core switch S312 outputs the second core monitoring voltage VCM2 at a voltage level of the ground voltage VSS to the sixth through-via T312. Thus, the first core die 121-1 connects the ground voltage VSS to the fifth through-via T311 and the sixth through-via T312.

In this example, the third core switch (not shown) of the second core die 121-2 outputs the third core monitoring voltage VCM3 at a voltage level of the ground voltage VSS to the seventh through-via T313. The fourth core switch (not shown) of the second core die 121-2 outputs the fourth core monitoring voltage VCM4 at a voltage level of the ground voltage VSS to the eighth through-via T314. Thus, the second core die 121-2 connects the ground voltage VSS to the seventh through-via T313 and the eighth through-via T314.

Subsequently, the base die 120, the first core die 121-1, and the second core die 121-2 are vertically stacked.

When the base die 120 the core dies 121-1 to 121-L are stacked, and the voltage monitoring enable signal VMEN is disabled, the first base switch S211 of the base die 120 prevents connection between the first voltage monitoring pad P211 and a node connecting the first through-via T211 and the third through-via T213. When the base die 120 the core dies 121-1 to 121-L are stacked, the second base switch S212 prevents connection between the second voltage monitoring pad P212 and a node connecting the second through-via T212 and the fourth through-via T214. Thus, the base die 120 prevents connection between the first through-via T211, the third through-via T213, and the first voltage monitoring pad P211, and prevents connection between the second through-via T212, the fourth through-via T214, and the second voltage monitoring pad P212.

When the base die 120 the core dies 121-1 to 121-L are stacked, and when the voltage monitoring enable signal VMEN is disabled, the first core switch S311 of the first core die 121-1 prevents connection between the fifth through-via T311 and the core voltage control circuit 310. When the base die 120 the core dies 121-1 to 121-L are stacked, and when the voltage monitoring enable signal VMEN is disabled, the second core switch S312 prevents connection between the sixth through-via T312 and the core voltage control circuit 310. Thus, when the base die 120 the core die 121-1 to 121-L are stacked, the first core die 121-1 prevents connection between the fifth through-via T311 and the core voltage control circuit 310 and prevents connection between the sixth through-via T312 and the core voltage control circuit 310.

In this example, when the base die 120 the core die 121-1 to 121-L are stacked and when the voltage monitoring enable signal VMEN is disabled, the third core switch of the second core die 121-2 prevents connection between the seventh through-via T313 and the core voltage control circuit (not shown) of the second core die 121-2. When the base die 120 the core dies 121-1 to 121-L are stacked and when the voltage monitoring enable signal VMEN is disabled, the fourth core switch of the second core die 121-2 prevents connection between the eighth through-via T314 and the core voltage control circuit of the second core die 121-2. Thus, when the base die 120 the core die 121-1 to 121-L are stacked, the second core die 121-2 prevents connection between the seventh through-via T313 and the core voltage control circuit of the second core die 121-2 and connection between the eighth through-via T314 and the core voltage control circuit of the second core die 121-2.

When the voltage monitoring enable signal VMEN is enabled and the first to fourth target codes TCD<1:4> are input in a first logic level combination, the core voltage control circuit 310 of the first core die 121-1 generates the first core monitoring voltage VCM1 from one of the ground voltage VSS, the peripheral voltage VPERI, and the core voltage VCORE and generates the second core monitoring voltage VCM2 from one of the ground voltage VSS, the high voltage VPP, and the low voltage VBB.

When the voltage monitoring enable signal VMEN is enabled, the first core switch S311 of the first core die 121-1 connects the fifth through-via T311 to the first floating node FLT1 and outputs the first core monitoring voltage VCM1 to the fifth through-via T311. When the voltage monitoring enable signal VMEN is enabled, the second core switch S312 connects the sixth through-via T312 to the second floating node FLT2 and outputs the second core monitoring voltage VCM2 to the sixth through-via T312.

During this example, the second core die 121-2 prevents generation of the third core monitoring voltage VCM3 and the fourth core monitoring voltage VCM4.

The first base switch S211 of the base die 120 outputs the first core monitoring voltage VCM1 to the first voltage monitoring pad P211 when the voltage monitoring enable signal VMEN is enabled. The second base switch S212 outputs the second core monitoring voltage VCM2 to the second voltage monitoring pad P212 when the voltage monitoring enable signal VMEN is enabled. The base die 120 monitors a voltage level of the first core monitoring voltage VCM1 output to the first voltage monitoring pad P211. The base die 120 monitors the voltage level of the second core monitoring voltage VCM2 output to the second voltage monitoring pad P212.

According to an embodiment of the present disclosure, the base die 120 and the plurality of core dies 121-1 to 121-L of the memory system 1 are stacked after connecting the through-vias to the ground voltage VSS prior to the voltage monitoring operation, thereby preventing through-via defects caused by charge accumulating in the through-vias. The memory system 1 monitors the internal voltage of a selected core die during the voltage monitoring operation after the base die 120 and a plurality of core dies 121-1 to 121-L are stacked. The memory system 1 generates an internal voltage higher than the power supply voltage VDD, referred to as a higher internal voltage, such as VPP, after the base die 120 and the plurality of core dies 121-1 to 121-L are stacked, voltage divides the higher internal voltage, and monitors the divided higher internal voltage. The memory system 1 generates the divided higher internal voltage by voltage division of the higher internal voltage and outputs the divided higher internal voltage using the through-vias, thereby preventing output of the higher internal voltage to the through-vias to protect the through-vias.

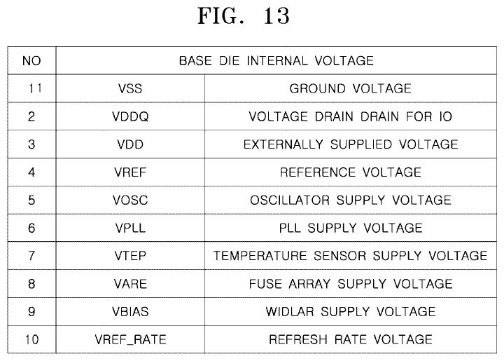

FIG. 13 is a table including internal voltage data monitored in a base die during a voltage monitoring operation according to an embodiment of the present disclosure.

VSS is used as a ground voltage. VDDQ is used as a voltage supplied to a buffer that transmits data and the like. VDD is an externally supplied voltage. VREF is used as a voltage that distinguishes a logic level of data and is used as a reference in a comparison circuit. VOSC is used as a voltage supplied to an oscillator. VPLL is used as a voltage supplied to a PLL circuit. VTEP is used as a voltage supplied to a temperature sensor. VARE is used as a voltage supplied to a fuse array circuit. VBIAS is used as a voltage supplied to a voltage generation circuit such as a Widlar voltage generation circuit. VREF_RATE is used as a voltage for detecting a refresh cycle.

The internal voltages monitored in the base die shown in FIG. 13 are examples of the internal voltages, and the internal voltages monitored in the base die may vary depending on the embodiment.

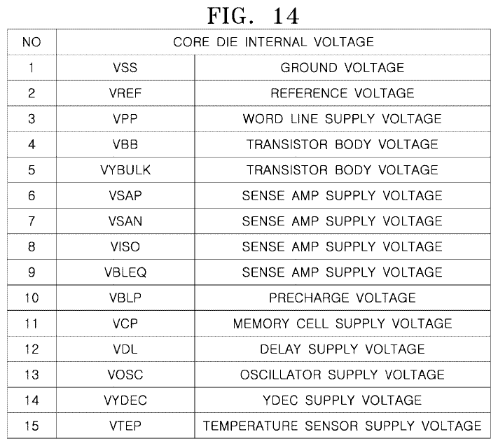

FIG. 14 is a table including internal voltage data monitored in a core die during a voltage monitoring operation according to an embodiment of the present disclosure.

VSS is used as a ground voltage. VREF is used as a voltage to distinguish a logic level of data and as a reference in a comparison circuit. VPP is used as a voltage to activate word lines included in a core region. VBB and VYBULK are used as voltages supplied to a base of each transistor used in the core region and a peripheral region, for example, to bias the transistor. VSAP, VSAN, VISO, and VBLEQ are used as voltages supplied to a sense amplifier. VBLP is used as a voltage to pre-charge bit lines included in the core region. VCP is used as a voltage supplied to memory cells included in the core region. VDL is used as a voltage supplied to a delay circuit. VOSC is used as a voltage supplied to an oscillator or a charge pump circuit. VYDEC is used as a voltage supplied to a decoder that selects a memory cell. VTEP is used as a voltage supplied to a temperature sensor.

The internal voltages monitored in the core dies shown in FIG. 14 are examples of the internal voltages, and the internal voltages monitored in the core dies may vary depending on the embodiment.

According to an embodiment of the present disclosure, the base die 120 and the plurality of core dies 121-1 to 121-L of the memory system 1 are stacked after connecting the through-vias to the ground voltage VSS prior to the voltage monitoring operation, thereby preventing through-via defects caused by charge accumulating in the through-vias. The memory system 1 monitors the internal voltage of a selected core die during the voltage monitoring operation after the base die 120 and the plurality of core dies 121-1 to 121-L are stacked. The memory system 1 generates an internal voltage higher than the power supply voltage VDD, referred to as a higher internal voltage, after the base die 120 and the plurality of core dies 121-1 to 121-L are stacked, voltage divides the higher internal voltage, and monitors the divided higher internal voltage. The memory system 1 generates the divided higher internal voltage by voltage division of the higher internal voltage and outputs the divided higher internal voltage using the through-vias, thereby preventing output of the higher internal voltage to the through-vias to protect the through-vias.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. The scope of the present disclosure is not limited to the descriptions, and all distinctive features within an equivalent scope should be construed as included in the present disclosure. All changes within the meaning and range of equivalency of the claims are included within their scope.

What is claimed is:

1. A memory device comprising:
a first core die stacked with a second core die; and
a base die configured to monitor a first core monitoring voltage output from the first core die and a second core monitoring voltage output from the second core die through a voltage monitoring pad;
wherein the first core die is stacked over the base die through a first through-via connected to the voltage monitoring pad and outputs the first core monitoring voltage to the voltage monitoring pad through the first through-via; and
wherein the second core die is stacked over the first core die through a second through-via connected to the voltage monitoring pad and outputs the second core monitoring voltage to the voltage monitoring pad through the second through-via.
wherein the voltage monitoring pad is connected to a ground voltage.

2. The memory device of claim 1,
wherein the first core die outputs one of a first peripheral voltage and a first core voltage as the first core monitoring voltage; and
wherein the first core die prevents generation of the first core monitoring voltage when the second core monitoring voltage is output from the second core die.

3. The memory device of claim 1,
wherein the second core die outputs one of a second peripheral voltage and a second core voltage as the second core monitoring voltage; and
wherein the second core die prevents generation of the second core monitoring voltage when the first core monitoring voltage is output from the first core die.

4. The memory device of claim 1,
wherein the first core die connects the first through-via to a first floating node upon entering a voltage monitoring operation; and
wherein the second core die connects the second through-via to a second floating node upon entering the voltage monitoring operation.

5. The memory device of claim 4, wherein the first floating node and the second floating node are in a floating state wherein connection outside the memory device is prevented.

6. The memory device of claim 1, wherein the base die comprises:
a third through-via connected to the first through-via and a fourth through-via connected to the second through-via;
a base switch connected between the voltage monitoring pad and the third through-via and the fourth through-via, and configured to output one of the first core monitoring voltage and the second core monitoring voltage to the voltage monitoring pad based on a voltage monitoring enable signal; and
a base voltage control circuit configured to output the ground voltage to the voltage monitoring pad based on the voltage monitoring enable signal.

7. The memory device of claim 1, wherein the first core die comprises:
a first core voltage control circuit configured to generate the first core monitoring voltage from one of a first peripheral voltage and a first core voltage based on a voltage monitoring enable signal; and
a first core switch connected to the first through-via and configured to output the first core monitoring voltage to the first through-via based on the voltage monitoring enable signal.

8. The memory device of claim 7, wherein the first core voltage control circuit comprises:
a first core selection signal generation circuit configured to generate a first core enable signal and a first plurality of core selection signals based on the voltage monitoring enable signal, a target code, and a core voltage code;
a first core voltage generation circuit configured to generate the first peripheral voltage and the first core voltage from a power supply voltage supplied from an external source; and
a first core selection transmission circuit configured to generate the first core monitoring voltage from one of the ground voltage, the first peripheral voltage, and the first core voltage based on the first core enable signal and the first plurality of core selection signals.

9. The memory device of claim 1, wherein the second core die comprises:
a second core voltage control circuit configured to generate the second core monitoring voltage from one of a second peripheral voltage and a second core voltage based on the voltage monitoring enable signal; and
a second core switch connected to the second through-via and configured to output the second core monitoring voltage to the second through-via based on the voltage monitoring enable signal.

10. The memory device of claim 9, wherein the second core voltage control circuit comprises:
a second core selection signal generation circuit configured to generate a second core enable signal and a second plurality of core selection signals based on the voltage monitoring enable signal, a target code, and a core voltage code;
a second core voltage generation circuit configured to generate the second peripheral voltage and the second core voltage from a power supply voltage supplied from an external source; and
a second core selection transmission circuit configured to generate the second core monitoring voltage from one of the ground voltage, the second peripheral voltage, and the second core voltage based on the second core enable signal and the second plurality of core selection signals.

11. A memory device comprising:
a core die; and
a base die configured to monitor a first core monitoring voltage output from the core die through a first voltage monitoring pad and a second core monitoring voltage output from the core die through a second voltage monitoring pad,
wherein the core die is stacked over the base die through a first through-via connected to the first voltage monitoring pad and a second through-via connected to the second voltage monitoring pad, outputs the first core monitoring voltage to the first voltage monitoring pad through the first through-via and outputs the second core monitoring voltage to the second voltage monitoring pad through the second through-via
wherein the first voltage monitoring pad and the second voltage monitoring pad are connected to a ground voltage.

12. The memory device of claim 11,
wherein the first core monitoring voltage is a voltage generated by dividing the power supply voltage, and
wherein the second core monitoring voltage is a voltage generated higher than a voltage level of the power supply voltage.

13. The memory device of claim 11,
wherein the core die connects the first through-via to a first floating node upon entering a voltage monitoring operation, and
wherein the core die connects the first through-via to a second floating node upon entering the voltage monitoring operation.

14. The memory device of claim 13, wherein the first floating node and the second floating node are in a floating state wherein connection outside the memory device is prevented.

15. The memory device of claim 11, wherein the base die comprises:
a third through-via connected to the first through-via and a fourth through-via connected to the second through-via;
a first base switch connected between the first voltage monitoring pad and the third through-via, and configured to output the first core monitoring voltage to the first voltage monitoring pad based on a voltage monitoring enable signal;
a second base switch connected between the second voltage monitoring pad and the fourth through-via, and configured to output the second core monitoring voltage to the second voltage monitoring pad based on the voltage monitoring enable signal; and
a base voltage control circuit configured to output the ground voltage to the first voltage monitoring pad and the second voltage monitoring pad based on the voltage monitoring enable signal.

16. The memory device of claim 15, wherein the base voltage control circuit is configured to:
generate a first base monitoring voltage from one of the ground voltage, a reference voltage, and a temperature voltage based on the voltage monitoring enable signal and a base voltage code and output the first base monitoring voltage to the first voltage monitoring pad, and
generate a second base monitoring voltage from one of the ground voltage, a cyclic voltage, and a phase-locked loop (PLL) voltage based on the voltage monitoring enable signal and the base voltage code and output the second base monitoring voltage to the second voltage monitoring pad.

17. The memory device of claim 16, wherein the base voltage control circuit comprises:
a base voltage generation circuit configured to receive a power supply voltage and the ground voltage and generate the reference voltage, the temperature voltage, the cyclic voltage, and the PLL voltage;
a base selection signal generation circuit configured to generate a first plurality of base selection signals and a second plurality of base selection signals based on the voltage monitoring enable signal and the base voltage code;
a first base selection transmission circuit configured to generate the first base monitoring voltage from one of the ground voltage, the reference voltage, and the temperature voltage based on the first plurality of base selection signals and output the first base monitoring voltage to the first voltage monitoring pad; and
a second base selection transmission circuit configured to generate the second base monitoring voltage from one of the ground voltage, the cyclic voltage, and the PLL voltage based on the second plurality of base selection signals and output the second base monitoring voltage to the second voltage monitoring pad.

18. The memory device of claim 11, wherein the core die comprises:
a core voltage control circuit configured to divide a power supply voltage to generate a peripheral voltage and a core voltage, generate the first core monitoring voltage from one of the peripheral voltage and the core voltage, generate a high voltage and a low voltage based on the power supply voltage, and generate the second core monitoring voltage from one of the high voltage and the low voltage after generating the first core monitoring voltage and the second core monitoring voltage from the ground voltage based on a voltage monitoring enable signal;
a first core switch connected to the first through-via and configured to output the first core monitoring voltage to the first through-via based on the voltage monitoring enable signal; and
a second core switch connected to the second through-via and configured to output the second core monitoring voltage to the second through-via based on the voltage monitoring enable signal.

19. The memory device of claim 18, wherein the core voltage control circuit comprises:
a core selection signal generation circuit configured to generate a core enable signal, a first plurality of core selection signals, and a second plurality of core selection signals based on the voltage monitoring enable signal, a target code, and a core voltage code;
a core voltage generation circuit configured to generate the ground voltage, divide the voltage level of the power supply voltage to generate the peripheral voltage and the core voltage and to generate the high voltage and the low voltage based on the power supply voltage;
a first core selection transmission circuit configured to generate the first core monitoring voltage from one of the ground voltage, the peripheral voltage, and the core voltage based on the core enable signal and the first plurality of core selection signals; and
a second core selection transmission circuit configured to generate the second core monitoring voltage from one of the ground voltage, the high voltage, and the low voltage based on the core enable signal and the second plurality of core selection signals.

20. A memory system comprising:
an interposer stacked over a substrate; and
a memory device and a processor stacked over the interposer and connected through a plurality of interconnections inside the interposer,
wherein the memory device comprises a base die and a plurality of core dies stacked over the interposer and using a plurality of through-vias;
wherein, the plurality of core dies generates a core monitoring voltage from a peripheral voltage and a core voltage and outputs the core monitoring voltage to the plurality of through-vias;
wherein the base die receives the core monitoring voltage output from one of the plurality of core dies through the plurality of through-vias connected to a voltage monitoring pad; and
wherein the processor monitors the core monitoring voltage at the voltage monitoring pad;
wherein the plurality of through-vias connected to ground voltage.

21. The memory system of claim 20, wherein when a first core die of the plurality of core dies outputs the core monitoring voltage, and the plurality of core dies except for the first core dies prevents generation of the core monitoring voltage.

22. The memory system of claim 20, wherein the plurality of core dies connects the plurality of through-vias to a floating node upon entering a voltage monitoring operation.

23. The memory system of claim 22, wherein the floating node is in a floating state wherein connection outside the memory device is prevented.

24. The memory system of claim 20, wherein the base die comprises:
a base switch connected between the plurality of through-vias and the voltage monitoring pad and configured to output the core monitoring voltage to the voltage monitoring pad based on the voltage monitoring enable signal; and
a base voltage control circuit configured to output the ground voltage to the voltage monitoring pad based on the voltage monitoring enable signal.

25. The memory system of claim 24, wherein the base voltage control circuit is configured to:
generate a base monitoring voltage from one of the ground voltage, a reference voltage, and a temperature voltage based on the voltage monitoring enable signal and a base voltage code, and
output the base monitoring voltage to the voltage monitoring pad.

26. The memory system of claim 25, wherein the base voltage control circuit comprises:
a base voltage generation circuit configured to receive a power supply voltage and the ground voltage and to generate the reference voltage and the temperature voltage;
a base selection signal generation circuit configured to generate a first plurality of base selection signals based on the voltage monitoring enable signal and the base voltage code; and
a base selection transmission circuit configured to generate the base monitoring voltage from one of the ground voltage, the reference voltage, and the temperature voltage based on the first plurality of base selection signals and apply the base monitoring voltage to the voltage monitoring pad.

27. A method comprising:
connecting to ground voltage a first through-via and a second through-via, wherein a core die is stacked over a base die through a first through-via connected to a first voltage monitoring pad and a second through-via connected to a second voltage monitoring pad;
outputting the first core monitoring voltage to the first voltage monitoring pad through the first through-via and outputting the second core monitoring voltage to the second voltage monitoring pad through the second through-via; and
monitoring, by the base die, a first core monitoring voltage output from the core die through a first voltage monitoring pad and a second core monitoring voltage output from the core die through a second voltage monitoring pad.
